(19) United States
(12) Patent Application Publication
(10) Pub. No.: US 2025/0314961 A1
(43) Pub. Date: Oct. 9, 2025

(54) PHOTORESIST COMPOUNDS AND METHODS OF FORMING PATTERNS USING THE SAME

(71) Applicant: Samsung Electronics Co., Ltd., Suwon-si (KR)

(72) Inventors: Sanghyun Je, Suwon-si (KR); Junsoo Kim, Suwon-si (KR); Hyereun Kim, Suwon-si (KR); Sooyoung Choi, Suwon-si (KR)

(21) Appl. No.: 19/089,434

(22) Filed: Mar. 25, 2025

(30) Foreign Application Priority Data
Apr. 4, 2024 (KR) 10-2024-0046199

(51) Int. Cl. G03F 7/004; G03F 7/20

(52) U.S. Cl. CPC G03F 7/0042; G03F 7/0045; G03F 7/2004

(57) ABSTRACT

A photoresist compound includes a metal organic framework having pores therein, and photoreactive materials within the pores, wherein the metal organic framework includes metal cores, and linkers bonded to the metal cores, wherein the photoreactive materials include at least one of a photo-acid generator and a photodecomposable quencher.

### CROSS-REFERENCE TO RELATED APPLICATION

This application is based on and claims priority under 35 U.S.C. § 119 to Korean Patent Application No. 10-2024-0046199, filed Apr. 4, 2024, in the Korean Intellectual Property Office, the disclosure of which is incorporated by reference herein in its entirety.

### FIELD

The inventive concept relates to a photoresist compound, and more particularly, to a photoresist compound used for patterning.

### BACKGROUND

As the electronics industry has made progress, the demand for high integration of semiconductor devices is increasingly intensifying. Accordingly, various problems arise in a patterning process to form fine patterns, making it increasingly difficult to implement semiconductor devices. An exposure process using extreme ultraviolet (EUV) rays has been introduced to form fine patterns.

EUV rays may have a small number of photons per unit volume due to their short wavelength. Accordingly, an EUV ray resist may have a low absorption rate with respect to EUV rays. Patterns formed by EUV lithography processes have a problem of line edge roughness (LER).

Chemically amplified resist (CAR) has been used as a resist in an EUV exposure process. However, in the case of a patterning process using chemically amplified resist, a problem arises in that patterns are formed with non-uniform distribution.

### SUMMARY

The inventive concept provides a resist pattern having a uniform critical dimension and uniform shape, and a photoresist compound used therein.

According to an aspect of the inventive concept, there is provided a photoresist compound including a metal organic framework having pores therein, and photoreactive materials within the pores, wherein the metal organic framework includes a plurality of metal cores, and one or more linkers bonded to each of the plurality of metal cores, wherein the photoreactive materials include at least one of a photo-acid generator and a photodecomposable quencher.

According to another aspect of the inventive concept, there is provided a photoresist compound including a metal organic framework having pores therein, a photo-acid generator within one of the pores of the metal organic framework, and a photodecomposable quencher within another one of the pores of the metal organic framework.

According to another aspect of the inventive concept, there is provided a pattern formation method including forming, on a substrate, an etching target layer, forming a resist film by applying a photoresist compound onto the etching target layer, and patterning the resist film to form resist patterns, wherein the photoresist compound include a metal organic framework having pores therein, and photoreactive materials within the pores of the metal organic framework, wherein the photoreactive materials include at least one of a photo-acid generator and a photodecomposable quencher.

### BRIEF DESCRIPTION OF THE DRAWINGS

Embodiments will be more clearly understood from the following detailed description taken in conjunction with the accompanying drawings in which:

FIG. 1 is a diagram describing a photoresist compound according to some embodiments;

FIG. 2 is a diagram describing a photoresist compound according to some embodiments;

FIGS. 3A and 3B are diagrams describing a manufacturing process of a photoresist compound, according to some embodiments;

FIG. 4 is a diagram describing a manufacturing process of a photoresist compound, according to some embodiments;

FIGS. 5A to 5C are diagrams describing a manufacturing process of a photoresist compound, according to some embodiments;

FIGS. 6A to 6D are diagrams describing a pattern forming method according to some embodiments;

FIGS. 7A-7D are diagrams describing a pattern forming method according to some embodiments;

FIGS. 8A to 8C are diagrams describing a pattern forming method according to some embodiments;

FIGS. 9A to 9C are diagrams describing formation of a target pattern according to some embodiments; and

FIG. 10 is a plan view describing a resist pattern according to some embodiments.

### DETAILED DESCRIPTION OF THE EMBODIMENTS

In the present specification, hydrocarbons may include saturated hydrocarbons and unsaturated hydrocarbons. Saturated hydrocarbons may include chain saturated hydrocarbons and cyclic saturated hydrocarbons. Unsaturated hydrocarbons may include chain unsaturated hydrocarbons and cyclic unsaturated hydrocarbons.

“Substituted or unsubstituted” refers to an element substituted or unsubstituted with one or more substituents selected from the group consisting of a hydrogen atom, a deuterium atom, a halogen atom, a cyano group, a nitro group, an amino group, an oxide group, a phosphine sulfide group, a thio group, a carboxyl group, an amine group, an amide group, an alkyl group, an alkenyl group, an aryl group, and a heterocyclic group. Each of the above substituents may be substituted or unsubstituted. For example, a methyl amino group may be interpreted as an amino group. A halogen alkyl group may be interpreted as an alkyl group. As used herein, the alkyl group may be a linear alkyl group, a branched alkyl group, or a cyclic alkyl group.

In the present specification, the same reference numerals may refer to the same elements throughout. Hereinafter, photoresist compounds and pattern formation methods according to some embodiments are described.

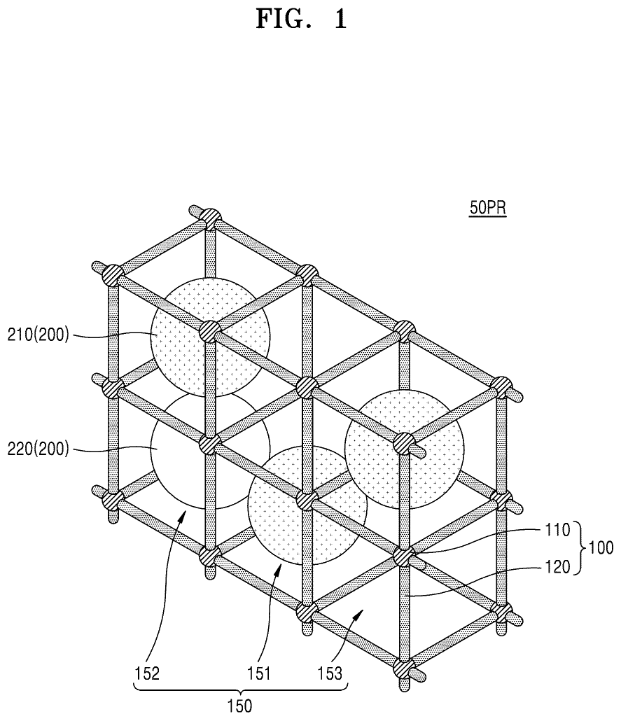

FIG. 1 is a diagram describing a photoresist compound according to some embodiments.

Referring to FIG. 1, a photoresist compound 50PR may include a metal organic framework (MOF) 100 and photoreactive materials 200. The MOF 100 may be a photoresist material. The MOF 100 may include metal cores 110 and linkers 120. The linkers 120 may be bonded to the metal cores 110. For example, the linkers 120 may be coordinate-bonded to the metal cores 110. Accordingly, the MOF 100 may have a three-dimensional structure. For example, the MOF 100 may have a three-dimensional grid structure, but is not limited thereto. The MOF 100 may include a plurality of units, and the units may be arranged repeatedly. The units may be arranged relatively regularly. As an example, the units may have a hexahedral shape or a cubic shape. The shape of the units is not limited thereto and may be modified in various manners.

The MOF 100 may have a plurality of pores 150 therein. The pores 150 may correspond to cavities defined by the metal cores 110 and the linkers 120. When the units of the MOF 100 have a repeating structure, the pores 150 may be arranged to repeat regularly. The pores 150 may have the same shape or similar shapes. The pores 150 may have the same size or similar sizes. The size of a component may include a width, length, and/or diameter of the component. In detail, the widths of the pores 150 may be the same or similar to each other, and the lengths of the pores 150 may be the same or similar to each other. The diameters of the pores 150 may be the same or similar to each other. The size of the pores 150 may be about 0.2 nm to about 10 nm, or any size range therein. As an example, the width of the pores 150 may be about 0.2 nm to about 10 nm, or any size range therein.

The metal cores 110 may include metal clusters. The metal cores 110 may include, for example, zinc (Zn), tin (Sn), and/or copper (Cu). However, the type of metal included in the metal cores 110 is not limited thereto.

The linkers 120 may be organic linkers. For example, the linkers 120 may include a substituted or unsubstituted hydrocarbon compound having 1 to 10 carbon atoms, or any range therein. As an example, the linkers 120 may include a hydrocarbon compound having 1 to 10 carbon atoms substituted with a halogen element. As an example, the halogen element may include fluorine (F). As another example, the halogen element may include chlorine, bromine, and/or iodine. As an example, the linkers 120 may include at least one of iodophenol and derivatives thereof, but the inventive concept is not limited thereto. In some embodiments, since the linkers 120 are substituted with halogen elements, the MOF 100 may have improved sensitivity and an improved absorption rate to extreme ultraviolet rays. Since the carbon number of the linkers 120 satisfies the above range, the size of the pores 150 may be controlled and the MOF 100 may be manufactured satisfactorily.

The photoresist compound 50PR may include an extreme ultraviolet (EUV) resist compound. For example, the photoresist compound 50PR may be used in a patterning process using extreme ultraviolet rays. When extreme ultraviolet rays are irradiated to the photoresist compound 50PR, the metal cores 110 may generate electrons. A chemical structure of the MOF 100 may be transformed by the electrons. Transformation of the chemical structure of the MOF 100 may include breaking of a bond between the linkers 120 and the metal cores 110 or transformation of a structure (e.g., chemical structure) of the linkers 120.

The photoreactive materials 200 may include at least one of a photo-acid generator (PAG) 210 and a photo decomposable quencher (PDQ) 220. The PAG 210 may be disposed within one of the pores 150. For example, the pores 150 may include first pores 151 and a second pore 152. The PAG 210 may be one of a plurality of PAGs 210. The PAGs 210 may be disposed (e.g., provided) within the first pores 151. The size of the PAGs 210 may be smaller than the width of the pores 150. Since the width of the pores 150 satisfies a condition of about 0.2 nm to about 10 nm, the PAGs 210 may be well trapped within the pores 150. Hereinafter, for simplicity, a singular PAG 210 will be described.

A content ratio of the PAG 210 may be about 30 wt % to about 50 wt % of the photoresist compound 50PR, or any range therein. When the content ratio of the PAG 210 satisfies the above condition, the photoresist compound 50PR may have improved reactivity to extreme ultraviolet rays.

The PAG 210 may be, for example, sulfonate, sulfonic acid, iodonium salts, or a mixture thereof. Sulfonates may include sulfonate salts, an anion of sulfonic acid, or sulfonic ester. Sulfonates may include alkyl sulfonates having 1 to 10,000 carbon atoms, or any range therein, aryl sulfonates having 1 to 10,000 carbon atoms, or any range therein, or benzyl sulfonates having 1 to 10,000 carbon atoms, or any range therein. Sulfonic acids may include alkyl sulfonic acid having 1 to 10,000 carbon atoms, or any range therein, aryl sulfonic acid having 1 to 10,000 carbon atoms, or any range therein, or benzyl sulfonic acid having 1 to 10,000 carbon atoms, or any range therein. Iodonium salts may include alkyl iodonium salts having 1 to 10,000 carbon atoms, or any range therein, aryl iodonium salts having 1 to 10,000 carbon atoms, or any range therein, or benzyl iodonium salts having 1 to 10,000 carbon atoms, or any range therein.

The PDQ 220 may be disposed (e.g., provided) within another one of the pores 150. For example, the PDQ 220 may be disposed (e.g., provided) within the second pore 152. Since the width of the pores 150 satisfies the condition of about 0.2 nm to about 10 nm, the PDQ 220 may be well trapped within the second pore 152.

The PDQ 220 may include a carboxylate-based material. The carboxylate-based material may include carboxylic acid, carboxylate salt, or carboxylate anion. The carboxylate-based material may include a substituted or unsubstituted alkyl carboxylate-based material having 1 to 10,000 carbon atoms, or any range therein, an aryl carboxylate-based material having 1 to 10,000 carbon atoms, or any range therein, or a benzyl carboxylate-based material having 1 to 10,000 carbon atoms, or any range therein.

A content ratio of the PDQ 220 may be less than the content ratio of the PAG 210. The content ratio of the PAG 210 may be about 3 times to about 500 times that of the PDQ 220, or any content ratio range therein. For example, the content ratio of the PDQ 220 may be about 1 wt % to about 10 wt % of the photoresist compound 50PR, or any range therein.

According to some embodiments, since the photoreactive materials 200 are disposed (e.g., provided) within the pores 150 of the MOF 100, stability of the photoresist compound 50PR may be improved. For example, the photoresist compound 50PR may be stably transported and stored for a relatively long period of time.

As an example, the MOF 100 may further have a third pore 153 in addition to the first pores 151 and the second pore 152. In some embodiments neither the PAGs 210 nor the PDQ 220 is disposed (e.g., provided) within the third pore 153. The third pore 153 may be an empty space or a space filled with a solvent.

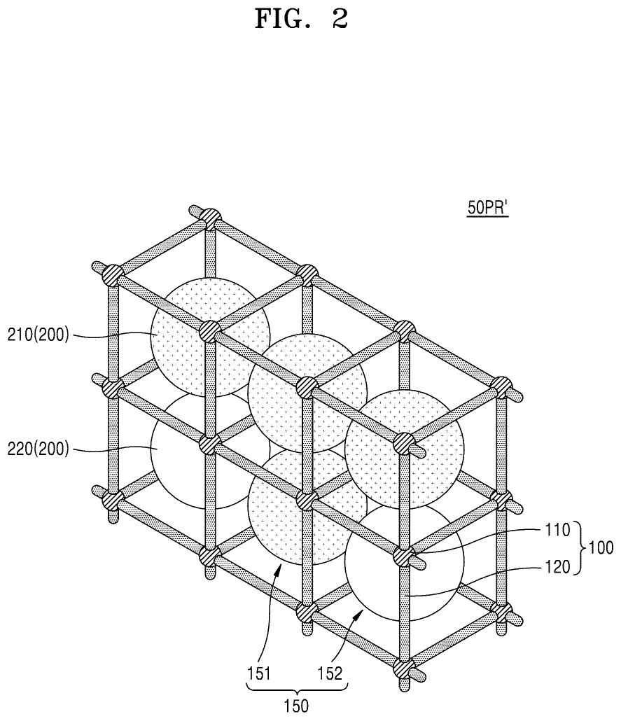

FIG. 2 is a diagram to describe a photoresist compound according to some embodiments.

Referring to FIG. 2, a photoresist compound 50PR′ may include an MOF 100 and photoreactive materials 200. The photoreactive materials 200 may include a PAG 210 and a PDQ 220. The MOF 100, the PAG 210, and the PDQ 220 may be substantially the same as those described with reference to the example of FIG. 1. However, the MOF 100 may have the first pores 151 and the second pore 152, but may not have the third pore 153 described with reference to FIG. 1. That is, the MOF 100 may not have empty pores. For example, a corresponding one of the PAGs 210 and the PDQ 220 may be disposed (e.g., provided) within each pore 150 of the MOF 100.

Hereinafter, a method of manufacturing a photoresist compound, according to some embodiments, will be described.

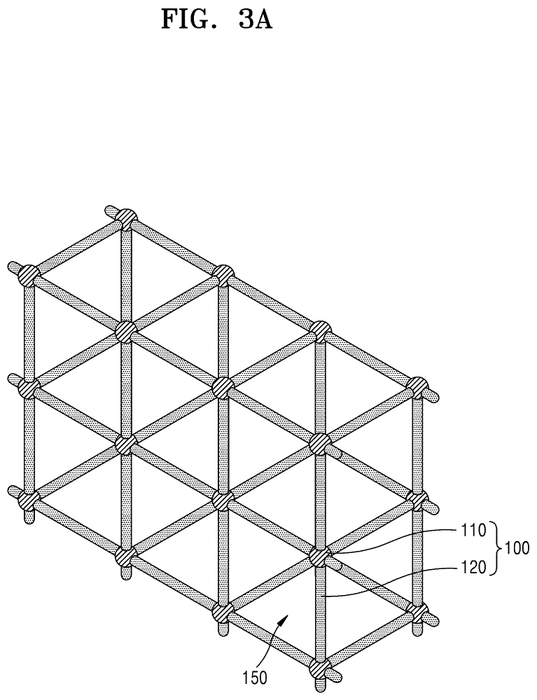

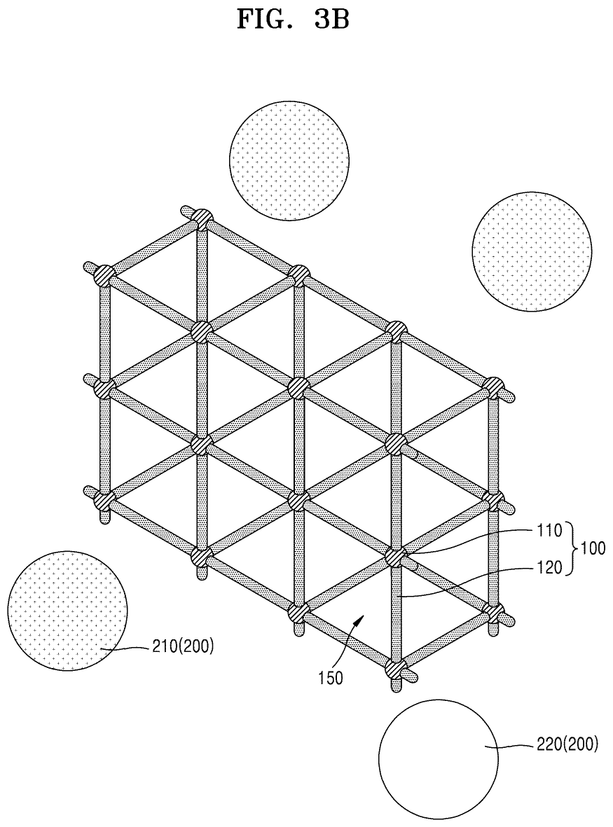

FIGS. 3A and 3B are diagrams describing a manufacturing process of a photoresist compound, according to some embodiments.

Referring to FIG. 3A, an MOF 100 may be prepared. The MOF 100 may include metal cores 110 and linkers 120. Preparing the MOF 100 may include synthesizing the MOF 100 from a precursor.

Referring to FIG. 3B, a solution including the photoreactive materials 200 may be added to the MOF 100 to prepare a mixed solution. As an example, a first solution and a second solution may be added to the MOF 100 to prepare a mixed solution. The first solution may be a solution including the PAG 210. The second solution may be a solution including the PDQ 220. Alternatively, a third solution may be added to the MOF 100 to prepare a mixed solution. The third solution may include the PAG 210 and the PDQ 220.

Referring to FIGS. 3B and 1 in turn, the PAG 210 and the PDQ 220 in the mixed solution may be impregnated into the pores 150 of the MOF 100. Accordingly, the preparation of the photoresist compound 50PR may be completed.

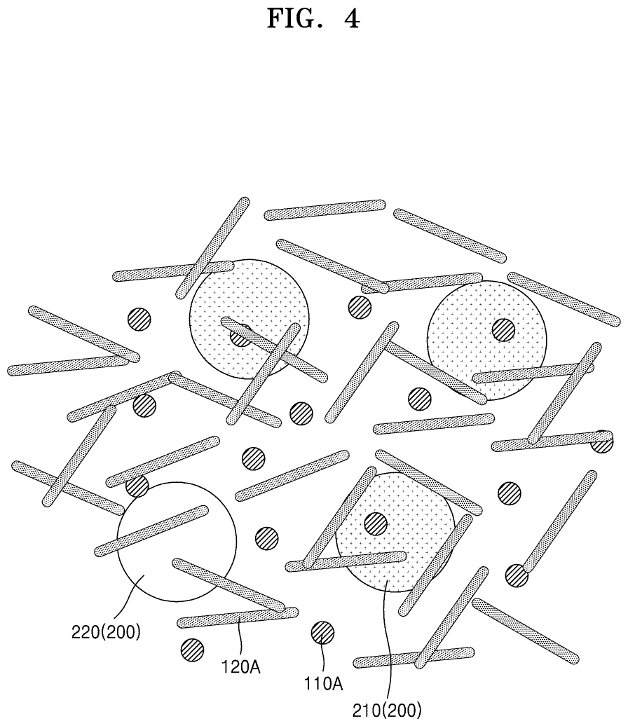

FIG. 4 is a diagram to describe a manufacturing process of a photoresist compound, according to some embodiments.

Referring to FIG. 4, a precursor may be added into a photoreactive solution. The precursor may include preliminary metal cores 110A and preliminary linkers 120A. In some embodiments, the preliminary linkers 120A may not be bonded to the preliminary metal cores 110A. The photoreactive solution may include the PAG 210 and the PDQ 220. The photoreactive solution may further include a solvent.

The preliminary linkers 120A, the preliminary metal cores 110A, the PAG 210, and the PDQ 220 may be mixed with each other. The photoreactive materials 200 may be disposed between the preliminary metal cores 110A and the preliminary linkers 120A. For example, the preliminary metal cores 110A and the preliminary linkers 120A may surround each photoreactive material 200.

Referring to FIGS. 4 and 1 in turn, the preliminary metal cores 110A and the preliminary linkers 120A may be bonded to each other through a reaction to produce the MOF 100. For example, the preliminary linkers 120A may react with the preliminary metal cores 110A to form the metal cores 110 and the linkers 120 bonded to each other. The preliminary metal cores 110A and the preliminary linkers 120A surround the photoreactive materials 200 and then are bonded to each other, and thus the metal cores 110 and the linkers 120 may properly surround the photoreactive materials 200. That is, the photoreactive materials 200 may be properly disposed (e.g., provided) within the pores 150 of the MOF 100. The photoresist compound 50PR may be manufactured according to the examples described above.

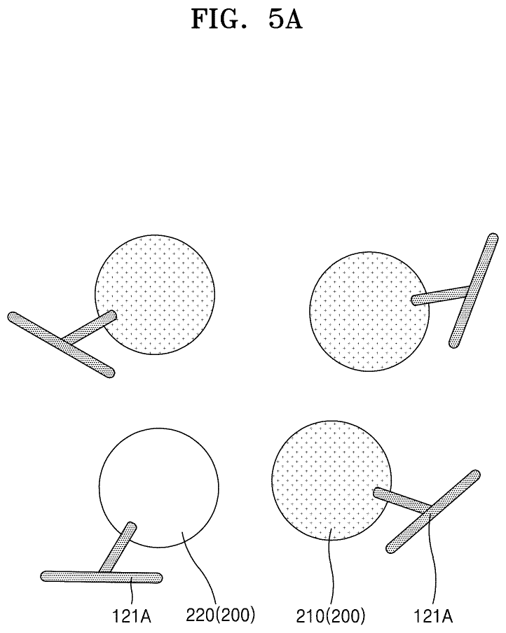

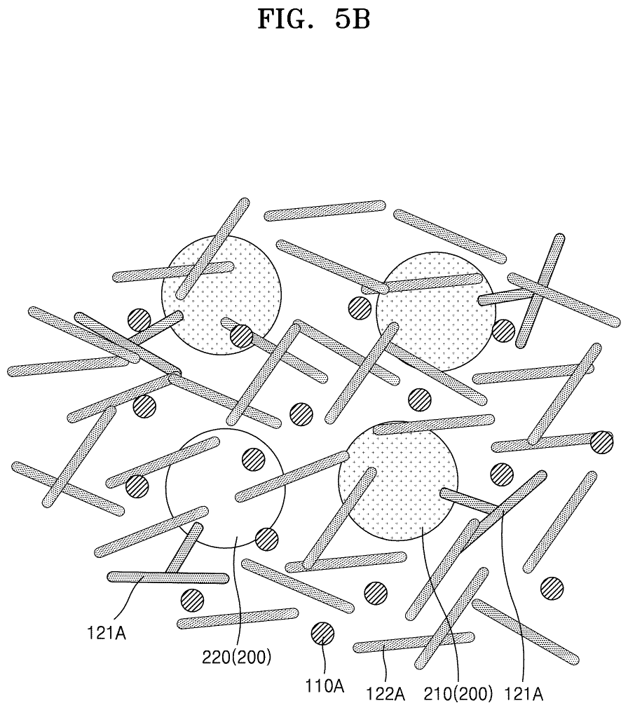

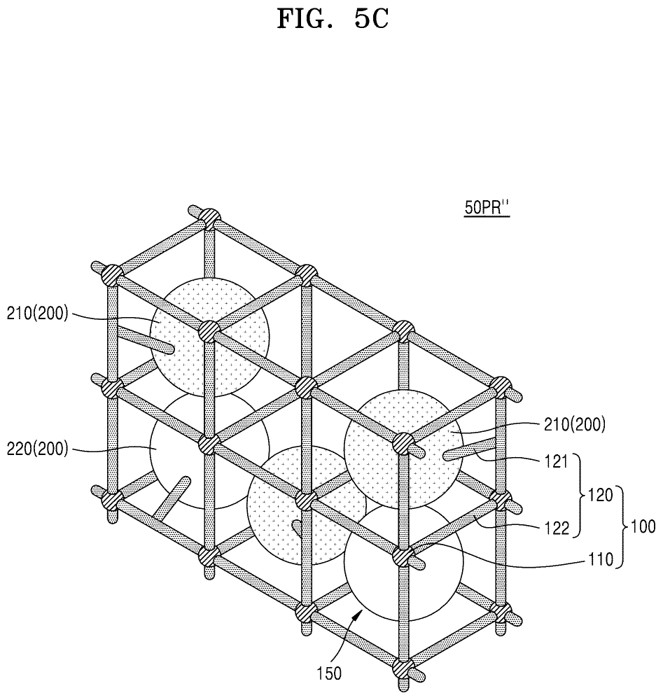

FIGS. 5A to 5C are diagrams to describe a manufacturing process of a photoresist compound, according to some embodiments.

Referring to FIG. 5A, first preliminary linkers 121A and photoreactive materials 200 may be prepared. The first preliminary linkers 121A may include substantially the same material as that described in the example of the preliminary linkers 120A described with reference to FIG. 4. However, the first preliminary linkers 121A may be bonded to the photoreactive materials 200. A bond between the preliminary linkers 121A and the photoreactive materials 200 may be a chemical bond. Preparing the first preliminary linkers 121A and the photoreactive materials 200 may include synthesizing the photoreactive materials 200 bonded to the first preliminary linkers 121A. For example, each of the PAG 210 and the PDQ 220 may be bonded to the first preliminary linkers 121A.

Referring to FIG. 5B, the preliminary metal cores 110A and second preliminary linkers 122A may be added to the first preliminary linkers 121A and the photoreactive materials 200. The second preliminary linkers 122A may include substantially the same material as described in the example of the preliminary linkers 120A described with reference to FIG. 4. However, the second preliminary linkers 122A may not be chemically bonded to the photoreactive materials 200.

Referring to FIGS. 5B and 5C in turn, the preliminary metal cores 110A and the first and second preliminary linkers 121A and 122A may be bonded to each other by reaction to produce the MOF 100. The MOF 100 may include the metal cores 110 and the linkers 120 bonded to each other. The linkers 120 may include first linkers 121 and second linkers 122. The first linkers 121 may be formed from the first preliminary linkers 121A. Accordingly, the first linkers 121 may be chemically bonded to the photoreactive materials 200 and the metal cores 110. The second linkers 122 may be formed from the second preliminary linkers 122A. The second linkers 122 are bonded to the metal cores 110, but may not be bonded to the photoreactive materials 200. Since the first linkers 121 are provided, the photoreactive materials 200 may be stably fixed to the first linkers 121. Accordingly, the photoreactive materials 200 may be stably disposed and trapped within the pores 150 of the MOF 100. According to the examples described above, the preparation of a photoresist compound 50PR″ may be completed.

In some embodiments, the method of preparing the photoresist compound described in the examples of FIGS. 3A and 3B and the method of preparing the photoresist compound described in the example of FIG. 4 may be applied to the preparation of the photoresist compound 50PR′ of FIG. 2.

In some embodiments, the method of preparing the photoresist compound described in the example of FIGS. 5A to 5C may be applied to the preparation of the photoresist compound 50PR in FIG. 1 and the photoresist compound 50PR′ in FIG. 2. In this case, the photoreactive materials 200 may be chemically bonded to the linkers 120.

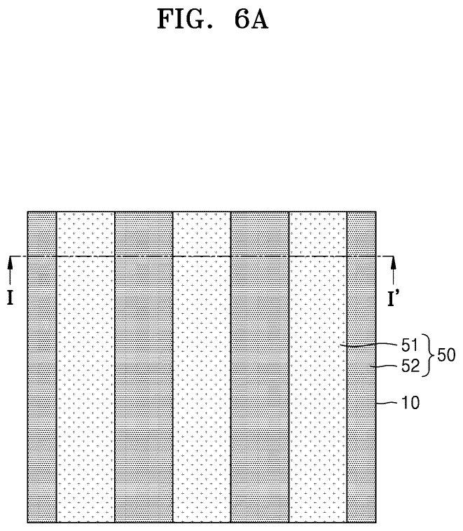

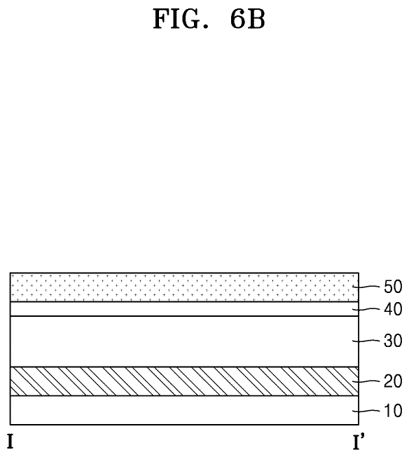

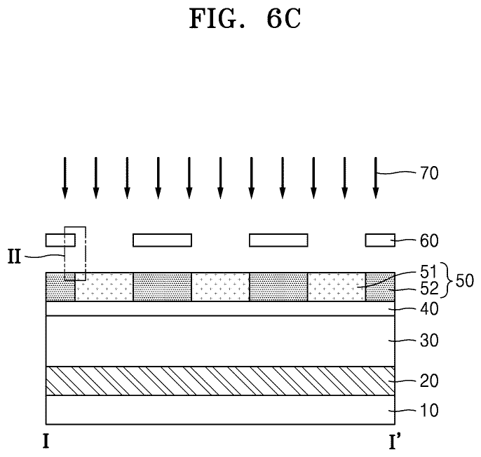

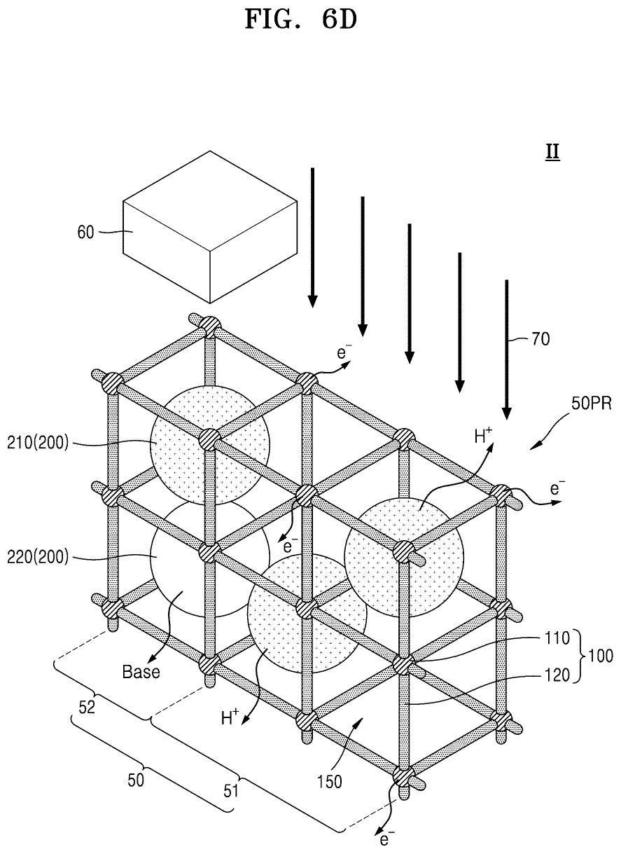

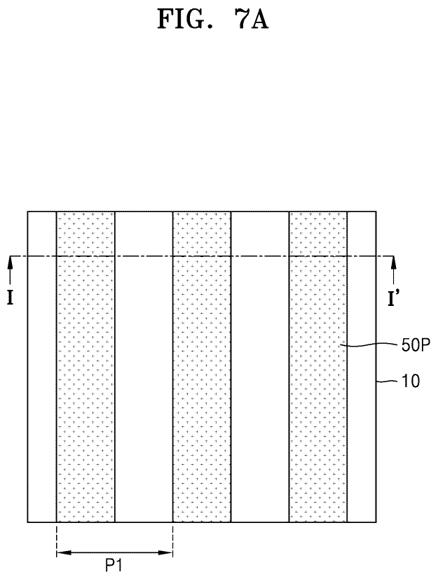

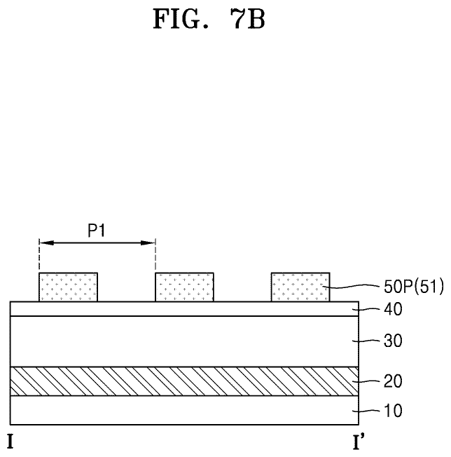

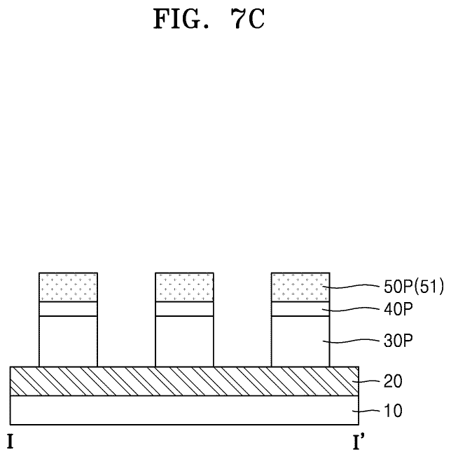

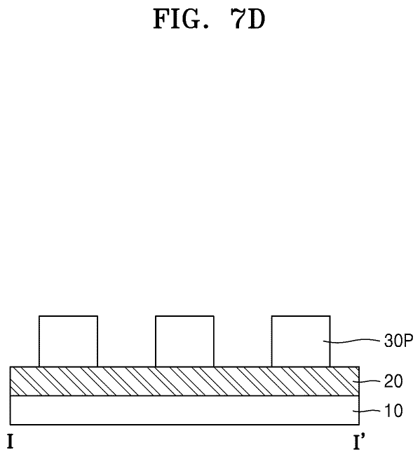

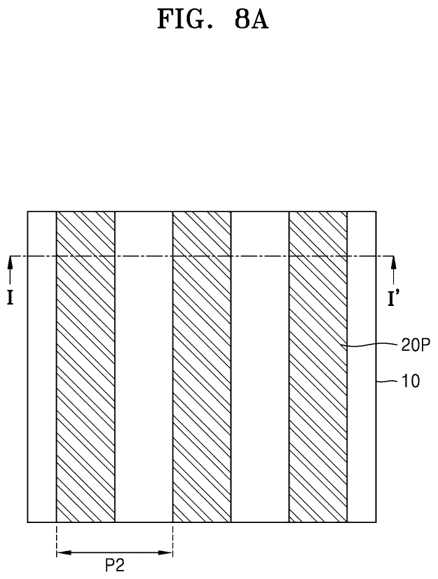

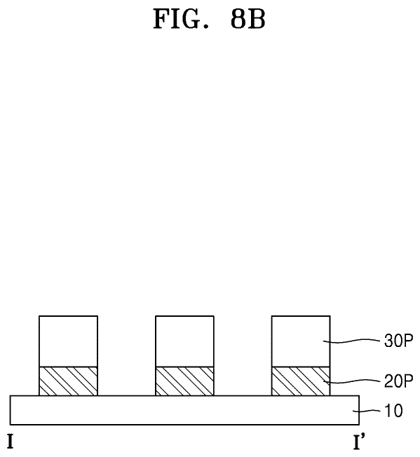

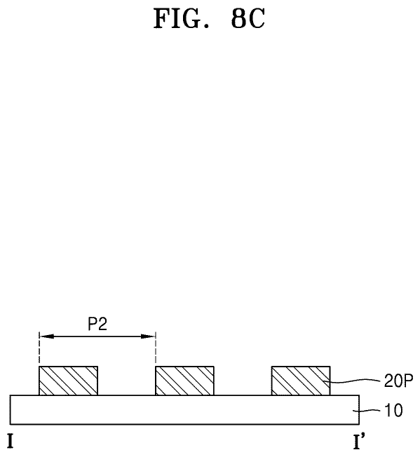

FIGS. 6A to 8C are diagrams describing a pattern forming method according to some embodiments. FIGS. 6A, 7A, and 8A are respectively plan views to describe a pattern forming method according to some embodiments. FIGS. 6B and 6C correspond to cross-sections taken along line I-I′ of FIG. 6A. FIG. 6D is an enlarged view of region II of FIG. 6C. FIGS. 7B to 7D correspond to cross-sections taken along line I-I′ of FIG. 7A. FIGS. 8B and 8C correspond to cross-sections taken along line I-I′ of FIG. 8A. Hereinafter, in the description of FIGS. 6B to 8C, FIG. 1, FIG. 2, or FIG. 5C will be referred to together.

Referring to FIGS. 6A and 6B, a substrate 10 on which an etching target layer 20, a mask layer 30, an under layer 40, and a resist film 50 are stacked may be prepared. The substrate 10 may include a semiconductor substrate or a semiconductor wafer.

The etching target layer 20 may be formed on an upper surface of the substrate 10. For example, the etching target layer 20 may include any one selected from a semiconductor material, a conductive material, and an insulating material, or a combination thereof. The semiconductor material may include silicon, germanium, doped silicon, and/or doped germanium. The conductive material may include a metal, a conductive metal nitride, or a metal-semiconductor compound. The conductive metal nitride may include titanium nitride and/or tantalum nitride. The metal may include tungsten, copper, aluminum, titanium, and/or tantalum. The metal-semiconductor compound may include tungsten silicide, cobalt silicide, and titanium silicide. The insulating material may include silicon oxide, silicon oxynitride, and/or a high-k dielectric material. The etching target layer 20 may be a single layer or a multi-layer. The etching target layer 20 may include a first portion and a second portion in a plan view. Although not shown, in some embodiments, at least one additional layer may be provided between the substrate 10 and the etching target layer 20.

The mask layer 30 may be formed on the etching target layer 20. The mask layer 30 may be a single layer or multiple layers. In some embodiments, when the mask layer 30 is a multi-layer, the mask layer 30 may include a first mask layer, a second mask layer, and a third mask layer that are stacked. Each of the first mask layer and the third mask layer may include a silicon film, a silicon oxide film, a silicon nitride film, a silicon oxynitride film, or a metal film. The metal film may include a titanium film, a tungsten film, a titanium oxide film, or a titanium nitride film. The silicon film may be an amorphous silicon film, a single crystal silicon film, or a polycrystalline silicon film. For example, the first mask layer and the third mask layer may include the same or different materials. The second mask layer may be provided between the first mask layer and the third mask layer. The second mask layer may include a different material from those of the first and third mask layers. The second mask layer may include a spin on hardmask (SOH) film, a spin-on carbon (SOC) film, or an amorphous carbon film. A thickness of the second mask layer may be greater than that of the first mask layer and that of the third mask layer, but is not limited thereto.

The under layer 40 may be formed on the mask layer 30. The under layer 40 may include an organic material such as a polymer. The under layer 40 may support the resist film 50. The under layer 40 may attach the resist film 50 to the mask layer 30. Although not shown, in some embodiments, a blocking layer may be further formed between the mask layer 30 and the under layer 40. In this case, the blocking layer may include at least one of carbon (C), silicon (Si), germanium (Ge), and tin (Sn).

The resist film 50 may be formed on the etching target layer 20 to cover an upper surface of the under layer 40. The resist film 50 may be formed using the photoresist compound 50PR of FIG. 1, the photoresist compound 50PR′ of FIG. 2, or the photoresist compound 50PR″ of FIG. 5C. The resist film 50 may be formed, for example, by a coating method such as spin coating.

A first bake process may be performed on the resist film 50. The first bake process may include heat treating the resist film 50. The first bake process may be performed at a temperature of about 80° C. to about 130° C., or any temperature therein. Solvent and impurities in the resist film 50 may be removed through the first bake process.

Since the resist film 50 includes a photoresist compound (50PR in FIG. 1, 50PR′ in FIG. 2 or 50PR″ in FIG. 5C) according to some embodiments, the resist film 50 may have stability. For example, as the photoresist compound (50PR in FIG. 1, 50PR′ in FIG. 2, or 50PR″ in FIG. 5C) includes the MOF 100 and the photoreactive materials 200 in the MOF 100 and the pores 150 of the MOF 100, the resist film 50 may have stability. Additionally, storage stability of the resist film 50 may be improved.

Referring to FIGS. 6A, 6C, and 6D, an exposure process may be performed on the resist film 50. The exposure process may be an extreme ultraviolet (EUV) exposure process. Extreme ultraviolet rays 70 may be used as light in the exposure process. The extreme ultraviolet rays 70 may refer to ultraviolet rays having a wavelength of about 12 nm to about 14 nm, specifically, a wavelength of about 13.0 nm to about 13.9 nm, and more specifically, a wavelength of about 13.4 nm to about 13.6 nm.

Before the extreme ultraviolet rays 70 are irradiated, a photo mask 60 may be disposed on the resist film 50. The resist film 50 may include a first portion 51 and a second portion 52. The photo mask 60 may be disposed on the second portion 52 of the resist film 50. The photo mask 60 may have openings. The openings of the photo mask 60 may expose the first portion 51 of the resist film 50. The extreme ultraviolet rays 70 may be irradiated onto the first portion 51 of the resist film 50 and the photo mask 60. By exposure to the extreme ultraviolet rays 70, the chemical structure of the photoresist compound (50PR in FIG. 1) of the first portion 51 of the resist film 50 may be changed. For example, the chemical structure of the MOF 100 in the first portion 51 of the resist film 50 may be changed. In some embodiments, the second portion 52 of the resist film 50 may not be exposed to the extreme ultraviolet rays 70 by the photo mask 60. The chemical structure of the photoresist compound (50PR in FIG. 1) in the second portion 52 of the resist film 50 may not change. Accordingly, after irradiation of the extreme ultraviolet rays 70 is completed, the first portion 51 of the resist film 50 may have a different chemical structure from that of the second portion 52. Exposure of the resist film 50 will be described in more detail.

In FIG. 6D, for illustrative purposes, the resist film 50 is shown as including the photoresist compound 50PR as in the example of FIG. 1, but the inventive concept is not limited thereto. For example, the resist film 50 may include the photoresist compound 50PR′ in the example of FIG. 2 or the photoresist compound 50PR″ in the example of FIG. 5C rather than photoresist compound 50PR represented in the drawing.

Referring to FIG. 2, the photoresist compound 50PR′ may include an MOF 100 and photoreactive materials 200. The photoreactive materials 200 may include a PAG 210 and a PDQ 220. When the extreme ultraviolet rays 70 are irradiated onto the first portion 51 of the resist film 50, electrons may be generated in the metal cores 110 within the first portion 51. The chemical structure of the MOF 100 may be transformed by the electrons. Transformation of the chemical structure of the MOF 100 may include breaking of a bond between the linkers 120 and the metal cores 110 or decomposition of the linkers 120. As another example, the chemical structure of the linkers 120 may be changed. Since the metal cores 110 of the MOF 100 are repeatedly arranged, the amount of extreme ultraviolet rays absorbed by the metal cores 110 in the first portion 51 of the resist film 50 may be increased.

When the extreme ultraviolet rays 70 are irradiated onto the first portion 51 of the resist film 50, the PAG 210 in the first portion 51 may generate acid. Alternatively, the PAG 210 may generate acid by electrons (e⁻) generated from the metal cores 110. The acid may include, for example, hydrogen ions (H+). The acid may further facilitate changes in the chemical structure of the MOF 100 in the first portion 51 of the resist film 50. Since the PDQ 220 is provided, even if the dose of the extreme ultraviolet rays 70 is relatively small, the chemical structure of the first portion 51 of the resist film 50 may be sufficiently changed. Additionally, even if the width and pitch of the openings of the photo mask 60 are relatively small, the chemical structure of the first portion 51 of the resist film 50 may be sufficiently changed.

The second portion 52 of the resist film 50 may not be exposed to the extreme ultraviolet rays 70 by the photo mask 60. Accordingly, the metal cores 110 within the second portion 52 of the resist film 50 may not generate electrons. The PAG 210 in the second portion 52 of the resist film 50 may not generate acid. Accordingly, the chemical structure of the MOF 100 in the second portion 52 of the resist film 50 may not be changed.

Electrons or acid generated in the first portion 51 of the resist film 50 may move toward the second portion 52. According to some embodiments, the PDQ 220 is provided in the second portion 52 of the resist film 50, and thus, the PDQ 220 may prevent the acid or electrons from penetrating the second portion 52. Accordingly, the chemical changes in the MOF 100 in the second portion 52 of the resist film 50 may be further prevented. Accordingly, the first portion 51 and the second portion 52 of the resist film 50 may be formed at a desired position and with a desired shape and pitch.

Since the PDQ 220 is provided, the dose of the extreme ultraviolet rays 70 may be reduced in the exposure process. Since the content ratio of the PDQ 220 is 1 wt % to 10 wt %, the dose of the extreme ultraviolet rays 70 may be further reduced in the exposure process.

After the exposure process, the photo mask 60 may be removed.

A first bake process may be performed on the resist film 50. In some embodiments, the second bake process may be a post exposure bake (PEB) process. The first bake process may include heat treating the resist film 50. The first bake process may be performed at a temperature of about 80° C. to about 130° C., or any range therein.

Referring to FIGS. 7A and 7B, a development process may be performed on the resist film 50 to form a resist pattern 50P. The resist pattern 50P may be formed, for example, by an extreme ultraviolet lithography process. The extreme ultraviolet lithography process may include an extreme ultraviolet ray exposure process and a development process. The extreme ultraviolet ray exposure process is the same as that described in the examples of FIGS. 5C and 5D. The development process may be performed using a developer. Forming the resist pattern 50P may include removing the second portion 52 of the resist film 50. Since the first portion 51 of the resist film 50 has a different chemical structure from that of the second portion 52, the first portion 51 of the resist film 50 may not be removed by the developer. The resist pattern 50P may include a remaining portion, that is, the first portion 51 of the resist film 50.

The resist pattern 50P may expose an upper surface of the under layer 40. In a plan view, the resist pattern 50P may overlap a first portion of the etching target layer 20 and be spaced apart from a second portion of the etching target layer 20.

The resist pattern 50P may have a line shape in a plan view as illustrated in FIG. 7A. The resist pattern 50P may extend in a first direction. The first direction may be parallel to a lower surface of the substrate 10. The planar shape of the openings of the photo mask 60 in FIG. 5C may be designed to correspond to the planar shape of the resist pattern 50P. For example, if the resist pattern 50P is desired to be formed in a line shape from a plan view, the planar shape of the openings of the photo mask 60 may be designed to have a line shape. The planar shape of the resist pattern 50P may be modified in various ways.

A plurality of resist patterns 50P may be formed. For example, the resist pattern 50P described above may be one of a plurality of resist patterns 50P. Since the resist patterns 50P are formed through an extreme ultraviolet lithography process, the resist patterns 50P may have a relatively small pitch P1. For example, the pitch P1 of the resist patterns 50P may be about 24 nm to about 40 nm, or any range therein. Hereinafter, for simplicity of description, a single resist pattern 50P will be described.

When a pattern is formed by an extreme ultraviolet lithography process, sidewalls of the pattern may be uneven in a plan view. According to some embodiments, the resist pattern 50P may be manufactured using a photoresist compound (50PR in FIG. 1, 50PR′ in FIG. 2 or 50PR″ in FIG. 5C) according to the embodiments, and the photoresist compound (50PR in FIG. 1, 50PR′ in FIG. 2 or 50PR″ in FIG. 5C) may include the MOF 100. Accordingly, the LER characteristics of the resist pattern 50P may be improved. As described in the example of FIG. 1, the PAGs 210 are provided in the first pores 151 of the MOF 100, and thus the sensitivity of the photoresist compound 50PR to extreme ultraviolet rays may be improved, and the LER characteristics of the resist pattern 50P may be further improved. Since the content ratio of the PAG 210 is about 30 wt % to about 50 wt %, the LER characteristics of the resist pattern 50P may be further improved, and reactivity of the photoresist compound 50PR with respect to extreme ultraviolet rays may be improved. Since the PDQ 220 is disposed (e.g., provided) within the second pore 152 of the MOF 100, the LER characteristics of the resist pattern 50P may be further improved.

Referring to FIG. 7C, an etching process using the resist pattern 50P as an etch mask may be performed to etch the under layer 40 and the mask layer 30. According to some embodiments, a portion of the under layer 40 exposed by the resist pattern 50P may be removed through an etching process to form an under pattern 40P. The resist pattern 50P may expose a portion of the mask layer 30. The exposed portion of the mask layer 30 may be removed through an etching process to form a mask pattern 30P. The mask pattern 30P may expose an upper surface of the second portion of the etching target layer 20.

Referring to FIG. 7D, the resist pattern 50P and the under pattern 40P may be removed to expose an upper surface of the mask pattern 30P.

Referring to FIGS. 8A and 8B, an etching process using the mask pattern 30P as an etch mask may be performed to form a target pattern 20P. For example, the second portion of the etching target layer 20 may be etched. The first portion of the etching target layer 20 may not be exposed to the etching process due to the mask pattern 30P. After the etching process, the first portion of the etching target layer 20 may form the target pattern 20P.

Referring to FIGS. 8A and 8C, the mask layer 30 may be removed to expose an upper surface of the target pattern 20P. The target pattern 20P may be formed in the same or similar shape at a position corresponding to the resist pattern 50P in FIGS. 7A and 7B. A pitch P2 of the target pattern 20P may be the same or similar to the pitch P1 of the resist pattern 50P in FIGS. 7A and 7B. The pitch P2 of the target pattern 20P may be about 24 nm to about 40 nm, or any range therein.

The target pattern 20P may further include a metal element. The metal element may be the same as the metal element included in the resist pattern 50P of FIGS. 7A and 7B. The metal element may be the same metal as the metal cores 110 of the photoresist compound 50PR of FIG. 1, the photoresist compound 50PR′ of FIG. 2, or the photoresist compound 50PR″ of FIG. 5C. Some of the metal cores 110 included in the resist pattern 50P remain in the target pattern 20P and form a metal element. A concentration of the metal element in the target pattern 20P may be 10 ppm or less.

According to some embodiments, the target pattern 20P may be a component of a semiconductor device. For example, the target pattern 20P may be a semiconductor pattern, a conductive pattern, or an insulating pattern within a semiconductor device. As an example, the target pattern 20P may correspond to wiring of a dynamic random-access memory (DRAM) device or wiring of a logic device.

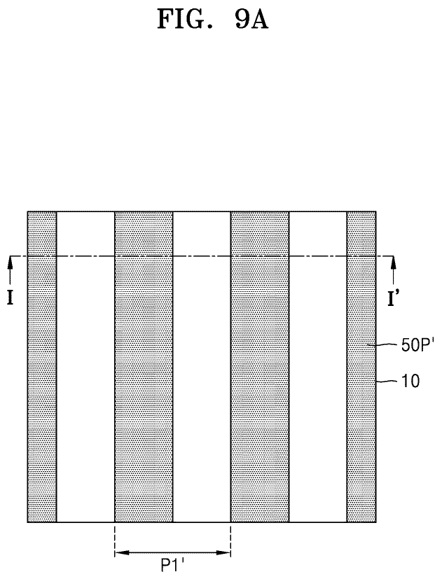

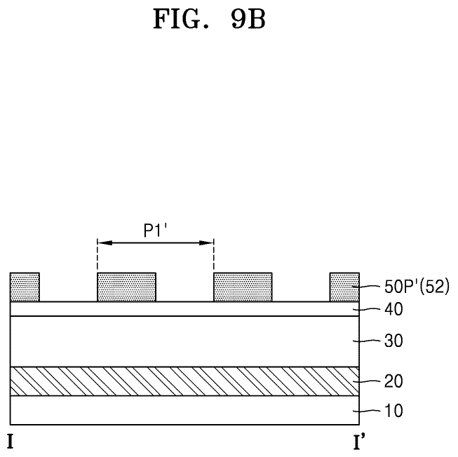

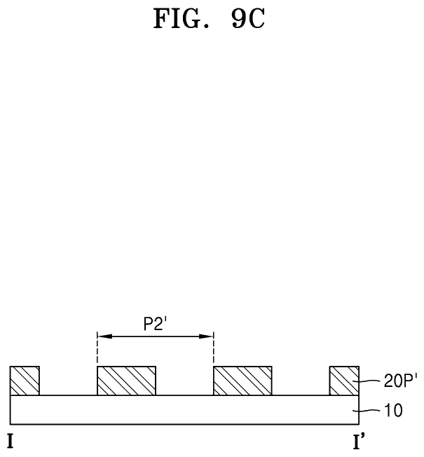

FIGS. 9A to 9C are diagrams to describe formation of a target pattern according to some embodiments.

Referring again to FIGS. 6A and 6C, the etching target layer 20, the mask layer 30, the under layer 40, and the resist film 50 may be sequentially formed on the substrate 10. An exposure process may be performed on the resist film 50. The extreme ultraviolet rays 70 may be irradiated onto the first portion 51 of the resist film 50.

Referring to FIG. 9A, a development process may be performed on the resist film 50 to form a resist pattern 50P′. Unlike the previous embodiments, the first portion 51 of the resist film 50 may be removed by a developer, thereby forming the resist pattern 50P′. The second portion 52 of the resist film 50 may not be removed by a developer. The resist pattern 50P′ may correspond to the second portion 52 of the resist film 50.

Referring to FIGS. 9B and 9C in turn, an etching process using the resist patterns 50P as an etch mask may be performed to etch the under layer 40 and the mask layer 30. Thereafter, the etching target layer 20 may be etched using the methods described in the examples of FIGS. 7C to 8C to form the target pattern 20P. The target pattern 20P may be formed in the same or similar shape at a position corresponding to the resist pattern 50P′ of FIGS. 9A and 9B. A pitch P2′ of the target pattern 20P may be the same or similar to a pitch P1′ of the resist pattern 50P′ of FIGS. 9A and 9B. The pitch P2′ of the target pattern 20P may be about 24 nm to about 40 nm, or any range therein.

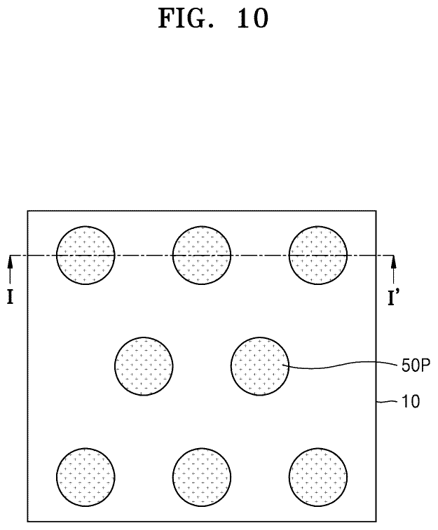

FIG. 10 is a plan view to describe a resist pattern according to some embodiments. A cross-section taken along line I-I′ of FIG. 10 may correspond to FIG. 7B.

Referring to FIG. 10, the resist pattern 50P may have a circular shape, an island shape, or an oval shape in a plan view. The resist pattern 50P may be one of a plurality of resist patterns 50P. The plurality of resist patterns 50P may be arranged in a zigzag shape or a honeycomb shape in a plan view.

The target pattern 20P may be a component of a semiconductor device. As an example, the target pattern 20P may correspond to conductive contacts of a DRAM device or conductive contacts of a logic device.

According to some embodiments of the inventive concept, the photoresist compound may include an MOF and photoreactive materials. The photoreactive materials may be disposed (e.g., provided) within the pores of the MOF. A resist pattern may be manufactured using the photoresist compound. The resist pattern may have improved LER characteristics. Deviations in size and shape between resist patterns may be reduced.

The detailed description of the inventive concept above is not intended to limit the inventive concept to the disclosed embodiments, and may be used in various other combinations, changes, and environments without departing from the gist of the inventive concept. The appended claims should be construed to include other embodiments as well.

While the inventive concept has been particularly shown and described with reference to embodiments thereof, it will be understood that various changes in form and details may be made therein without departing from the spirit and scope of the following claims.

What is claimed is:

1. A photoresist compound comprising:
a metal organic framework having pores therein; and
photoreactive materials disposed within the pores,
wherein the metal organic framework comprises:
a plurality of metal cores; and
one or more linkers bonded to each of the plurality of metal cores,
wherein the photoreactive materials comprise at least one of a photo-acid generator and a photodecomposable quencher.

2. The photoresist compound of claim 1, wherein the pores comprise a first pore and a second pore, and
the photoreactive materials comprise:
the photo-acid generator disposed within the first pore; and
the photodecomposable quencher disposed within the second pore.

3. The photoresist compound of claim 2, wherein a content ratio of the photo-acid generator is greater than a content ratio of the photodecomposable quencher.

4. The photoresist compound of claim 1, wherein the pores have a width of about 0.2 nm to about 10 nm.

5. The photoresist compound of claim 1, wherein the metal cores comprise zinc (Zn), tin (Sn), and/or copper (Cu), and
the one or more linkers each comprise substituted or unsubstituted hydrocarbon compounds having about 1 carbon atom to about 10 carbon atoms.

6. The photoresist compound of claim 1, wherein the one or more linkers each comprise a hydrocarbon compound having 1 to 10 carbon atoms substituted with a halogen element.

7. A photoresist compound comprising:
a metal organic framework having pores therein;
a photo-acid generator within one of the pores of the metal organic framework; and
a photodecomposable quencher within another one of the pores of the metal organic framework.

8. The photoresist compound of claim 7, wherein a content ratio of the photo-acid generator is greater than a content ratio of the photodecomposable quencher.

9. The photoresist compound of claim 7, wherein a content ratio of the photo-acid generator is about 3 times to about 500 times that of the photodecomposable quencher.

10. The photoresist compound of claim 8, wherein the content ratio of the photo-acid generator is about 30 wt % to about 50 wt %, and
a content ratio of the photodecomposable quencher is about 1 wt % to about 10 wt %.

11. The photoresist compound of claim 7, wherein the metal organic framework comprises:
a plurality of metal cores; and
one or more linkers each chemically bonded to the metal cores.

12. The photoresist compound of claim 7, wherein the photo-acid generator generates acid by extreme ultraviolet irradiation.

13. A pattern formation method comprising:
forming, on a substrate, an etching target layer;
forming a resist film by applying a photoresist compound onto the etching target layer; and
patterning the resist film to form resist patterns,
wherein the photoresist compound comprises:
a metal organic framework having pores therein; and
photoreactive materials within the pores of the metal organic framework,
wherein the photoreactive materials comprise at least one of a photo-acid generator and a photodecomposable quencher.

14. The pattern formation method of claim 13, wherein the photoreactive materials comprise:
the photo-acid generator within one of the pores; and
the photodecomposable quencher within another one of the pores.

15. The pattern formation method of claim 14, wherein a content ratio of the photo-acid generator is greater than a content ratio of the photodecomposable quencher.

16. The pattern formation method of claim 15, wherein the content ratio of the photo-acid generator is about 30 wt % to about 50 wt %,
and a content ratio of the photodecomposable quencher is about 1 wt % to about 10 wt %.

17. The pattern formation method of claim 13, wherein the resist film comprises a first portion and a second portion, and
the patterning the resist film comprises:
arranging a photo mask on the second portion of the resist film;
performing an extreme ultraviolet exposure process on the first portion of the resist film and the photo mask; and
removing either the first portion or the second portion of the resist film by using a developer,
wherein, after the extreme ultraviolet exposure process, the first portion of the resist film has a different chemical structure from that of the second portion.

18. The pattern formation method of claim 17, wherein, during the extreme ultraviolet exposure process, the photo-acid generator in the first portion of the resist film generates acid by extreme ultraviolet rays, and
a change in the chemical structure of the metal-organic framework is promoted by the acid.

19. The pattern formation method of claim 13, wherein a pitch of the resist patterns is about 24 nm to about 40 nm.

20. The pattern formation method of claim 14, further comprising:
performing an etching process by using the resist patterns as an etch mask; and
removing a portion of the etching target layer to form a target pattern,
wherein a concentration of a metal element in the target pattern is 10 ppm or less, and
the metal organic framework comprises a plurality of metal cores and one or more linkers bonded to each of the plurality of metal cores, and
the metal element comprises a same metal as the plurality of metal cores.
